(19) United States
(12) Patent Application Publication
(10) Pub. No.: US 2012/0268701 A1
(43) Pub. Date: Oct. 25, 2012

(54) DISPLAY DEVICE

(75) Inventors: Tadashi Nemoto, Osaka (JP); Hiromi Katoh, Osaka (JP); Christopher Brown, Osaka (JP)

(73) Assignee: SHARP KABUSHIKI KAISHA, Osaka (JP)

(21) Appl. No.: 13/515,918

(22) PCT Filed: Dec. 14, 2010
(86) PCT No.: PCT/JP2010/072495

§ 371 Date: Jul. 6, 2012

(30) Foreign Application Priority Data
Dec. 15, 2009 (JP) 2009-284191

(51) Int. Cl. G01J 3/51; H01L 33/08; G02F 1/1335

(52) U.S. Cl. 349/106; 250/226; 349/110; 438/24; 257/E33.044

(57) ABSTRACT

Disclosed is a display device provided with a photosensor, which can improve sensor sensitivity without affecting display. The display device includes: a photosensor (FS) provided in a display region (1); a visible light blocking filter (18) that blocks visible light, which is disposed on an optical path of light that enters through an image display surface and that reaches the photosensor (FS); and a wavelength conversion layer (24) that is disposed between the visible light blocking filter (18) and the photosensor (FS) and that converts light in a specific wavelength range, which includes a range outside of the visible light range, into visible light.

### TECHNICAL FIELD

The present invention relates to a display device with photosensors.

### BACKGROUND ART

Conventionally, a display device with photosensors, which has photodetector elements such as photodiodes in pixels thereof, for example, and is thereby capable of detecting a brightness of ambient light or capturing an image of an object that is near a display, has been disclosed. Such a display device with photosensors can be used as a display device equipped with a touch panel. As a conventional technology, a display device with sensors in which a backlight thereof includes a light source that emits light in a non-visible light range and a light source that emits light in a visible light range has been disclosed, for example (see Japanese Patent Application Laid-Open Publication No. 2008-262204, for example). In this display device with sensors, infrared light from an infrared light source is reflected by a finger or a pen on a display surface, and an infrared signal component enters photosensors through an infrared light transmissive filter. This infrared signal component is detected by the photosensors, and presence or absence of a touch can thereby be recognized. Photosensors made of a silicon material have lower sensitivity to light in the infrared range, and therefore, an output of the infrared light needs to be increased, causing the power consumption of the infrared light source to increase.

To solve this problem, a liquid crystal display device equipped with an infrared light source that emits infrared light, an infrared-visible light conversion layer that converts the infrared light into visible light, and photosensors that detect the visible light has been disclosed (see Japanese Patent Application Laid-Open Publication No. 2008-83677, for example).

### SUMMARY OF THE INVENTION

However, in the conventional technology, a displayed image on the liquid crystal panel is affected by the light in the visible wavelength range, which has been converted by the infrared-visible light conversion layer, thereby lowering the display quality.

Therefore, an object of the present invention is to provide a display device with photosensors that can improve the sensor sensitivity without affecting a display.

A display device of the present invention is a display device having a display region that displays an image, including: a photosensor in the display region; a visible light blocking filter that blocks visible light, the visible light blocking filter being disposed on an optical path of light that enters through a display surface of the image and that reaches the photosensor; and a wavelength conversion layer that converts light in a specific wavelength range, which includes a wavelength range outside of a visible light range, into visible light, the wavelength conversion layer being disposed between the visible light blocking filter and the photosensor.

According to the display device of the present invention, the sensor sensitivity can be improved without affecting the display.

### BRIEF DESCRIPTION OF THE DRAWINGS

FIG. 1 is a block diagram showing a schematic configuration of a TFT substrate included in a liquid crystal display device according to Embodiment 1.

FIG. 2 is an equivalent circuit diagram showing an arrangement of pixels and photosensors in a pixel region of a TFT substrate.

FIG. 3 is a diagram showing an example of a timing chart in driving a liquid crystal display device.

FIG. 4A is a top view of a region corresponding to one pixel in a pixel region of the liquid crystal display device according to Embodiment 1.

FIG. 4B is a cross-sectional view along the line X1-X′1 in FIG. 4A.

FIG. 4C is a cross-sectional view along the line Y1-Y′1 in FIG. 4A.

FIG. 5A is a top view of a region corresponding to one pixel in a pixel region 1 of a liquid crystal display device according to Embodiment 2.

FIG. 5B is a cross-sectional view along the line X2-X′2 in FIG. 5A.

FIG. 5C is a cross-sectional view along the line Y2-Y′2 in FIG. 5A.

FIG. 6 is a cross-sectional view showing an example of a configuration of a liquid crystal display device having an infrared light transmissive filter on a side of an opposite substrate.

FIG. 7 is an explanatory diagram for an example of a light beam in the liquid crystal display device according to Embodiment 1.

FIG. 8A is a graph showing an example of wavelength characteristics of a sensitivity of photosensors.

FIG. 8B is a graph showing an example of wavelength characteristics of light that is emitted from an infrared LED.

FIG. 8C is a graph showing an example of filter characteristics of an infrared light transmissive filter.

FIG. 8D is a graph showing an example of wavelength characteristics of sunlight.

FIG. 9 is a diagram showing a first configuration example of a backlight.

FIG. 10 is a diagram showing a second configuration example of the backlight.

FIG. 11 is a diagram showing a third configuration example of the backlight.

FIG. 12 is a diagram showing a fourth configuration example of the backlight.

FIG. 13 is a diagram showing a fifth configuration example of the backlight.

FIG. 14 is a cross-sectional view of the backlight shown in FIG. 13.

FIG. 15A is a top view of a region corresponding to one pixel in a pixel region of a liquid crystal display device according to Embodiment 3.

FIG. 15B is a cross-sectional view along the line X3-X′3 in FIG. 15A.

FIG. 15C is a cross-sectional view along the line Y3-Y′3 in FIG. 15A.

### DETAILED DESCRIPTION OF EMBODIMENTS

A display device of an embodiment of the present invention is a display device having a display region that displays an image, including: a photosensor in the display region; a visible light blocking filter that blocks visible light, the visible light blocking layer being disposed on an optical path of light that enters through a display surface of the image and that reaches the photosensor; and a wavelength conversion layer that converts light in a specific wavelength range, which includes a wavelength range outside of a visible light range, into visible light, the wavelength conversion layer being disposed between the visible light blocking filter and the photosensor (first configuration).

According to the first configuration, the visible light that entered through the display surface is blocked by the visible light blocking filter, but light in the specific wavelength range passes through the visible light blocking filter. The light having a wavelength of the prescribed range that passed through the visible light blocking filter is converted into visible light by the wavelength conversion layer, and thereafter reaches the photosensor. Because the wavelength conversion layer is disposed between the visible light blocking filter and the photosensor, the amount of components of the visible light that exits through the display surface after being converted by the wavelength conversion layer can be reduced. This allows for an improvement of the photosensor sensitivity without affecting the display.

In a second configuration, the display device of the first configuration further includes a color filter that is disposed in the display region and that is used for displaying the image, wherein the visible light blocking filter is made of the same material as that of the color filter. In this configuration, because the visible light blocking filter is made of the same material as that of the color filter, the manufacturing cost can be reduced.

A third configuration is the second configuration, wherein the visible light blocking filter is formed by laminating color filters of two colors among green, blue, and red. With this configuration, the sensor performance can be improved.

A fourth configuration is the third configuration, wherein the visible light blocking filter is formed by laminating three color filters of green, blue, and red. With this configuration, the sensor performance can be further improved.

A fifth configuration is the display device of any one of the first to fourth configurations, further including: a first substrate having a pixel circuit that displays the image; a liquid crystal layer; and a second substrate that faces the first substrate through the liquid crystal layer, wherein the photosensor is formed in the first substrate, and wherein at least one of the visible light blocking filter and the wavelength conversion layer is disposed between the photosensor and the liquid crystal layer. In this configuration, a gap between the photosensor and at least one of the visible light blocking filter and the wavelength conversion layer can be minimized. This can reduce effects of noise light such as ambient light that enters this gap or internal reflection light, that is, the noise light that enters the photosensor can be reduced, and as a result, the S/N ratio can be improved.

A sixth configuration is the display device of any one of the second to fourth configurations, further including: a first substrate having a pixel circuit that displays the image; a liquid crystal layer; and a second substrate that faces the first substrate through the liquid crystal layer, wherein the photosensor is formed in the first substrate, and wherein the color filter is disposed between the photosensor and the liquid crystal layer. In this configuration, the color filter is provided in the first substrate that includes the pixel circuit. This allows the visible light blocking filter to be disposed in the first substrate, and as a result, the S/N ratio of the photosensor can be improved.

A seventh configuration is the display device of any one of the first to sixth configurations, further including: a first substrate having a pixel circuit that displays the image; a liquid crystal layer; and a second substrate that faces the first substrate through the liquid crystal layer, wherein the photosensor and the pixel circuit are formed in the first substrate by using amorphous silicon or polysilicon. In this configuration, the photosensor and the pixel circuit can be formed in the same substrate by using the same material. As a result, the structure thereof can be simplified, and the manufacturing cost can be reduced.

An eighth configuration is the display device of any one of the first to seventh configurations, further including a prescribed wavelength light source that emits light in the specific wavelength range, wherein the photosensor detects, of light that was emitted from the prescribed wavelength light source, light that enters through the visible light blocking filter and the wavelength conversion layer.

A method for manufacturing a display device according to an embodiment of the present invention includes: forming a pixel circuit and a photosensor on a substrate; forming a visible light blocking filter that blocks visible light at a position that corresponds to the photosensor; and forming a wavelength conversion layer between the photosensors and the visible light blocking filter, the wavelength conversion layer converting light in a specific wavelength range, which includes a range outside of a visible light range, into visible light.

According to this manufacturing method, a display device with photosensors that can improve the sensor sensitivity without affecting a display can be manufactured.

Specific embodiments of the present invention will be explained below with reference to figures. In embodiments below, examples of configurations where the display device of the present invention is used for a liquid crystal display device will be described. The display device of the present invention is provided with photosensors, and can therefore be used as a display device with a touch panel that is capable of an input operation by detecting an object near a screen, a duplex display device provided with a display function and an imaging function, or the like.

For ease of explanation, respective figures that will be referred to below only illustrate principal members that are necessary for describing the present invention in a simplified manner among constituting members of embodiments of the present invention. Therefore, the display device according to the present invention may include appropriate constituting members that are not shown in the respective figures that are referred to in the present specification. Dimensions of members of the respective figures do not accurately represent dimensions of actual constituting members, dimensional relations of the respective members, or the like.

### Embodiment 1

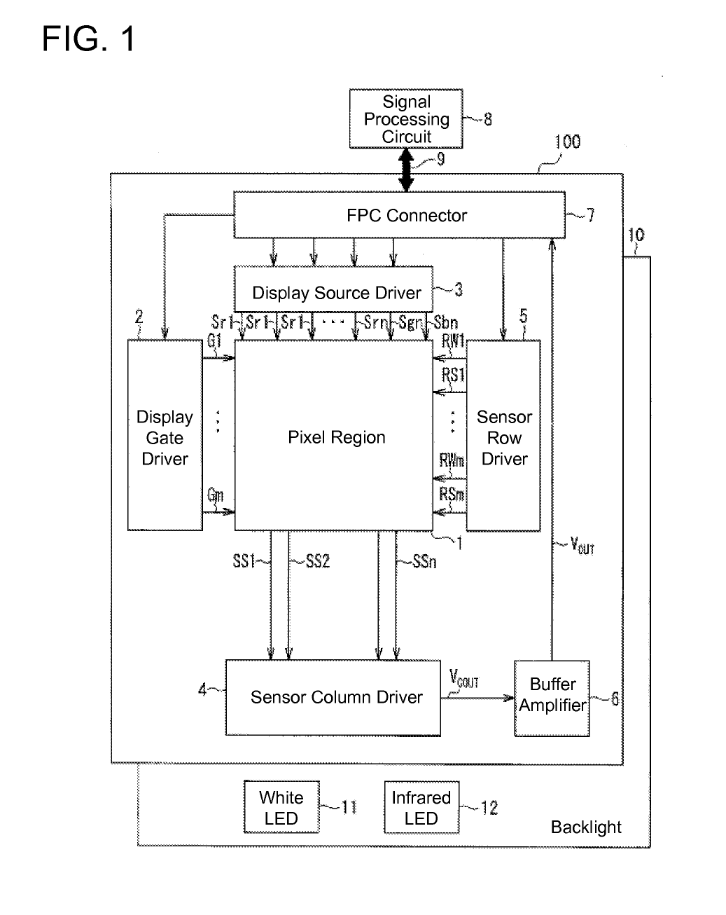

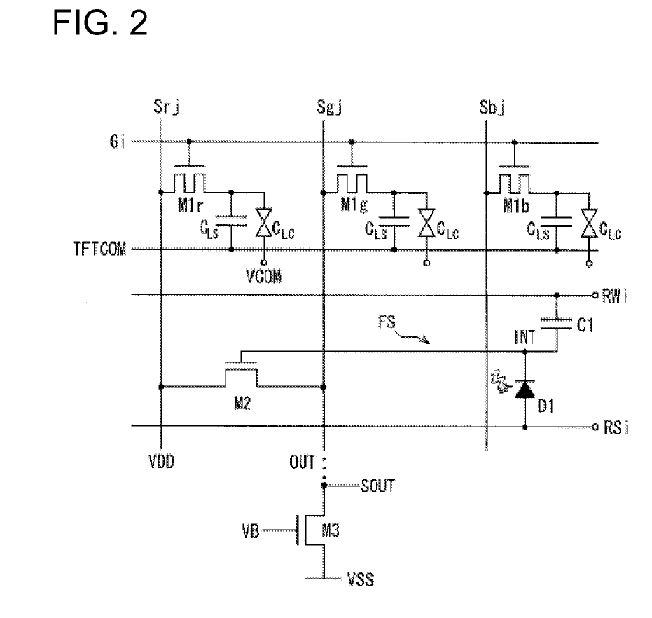

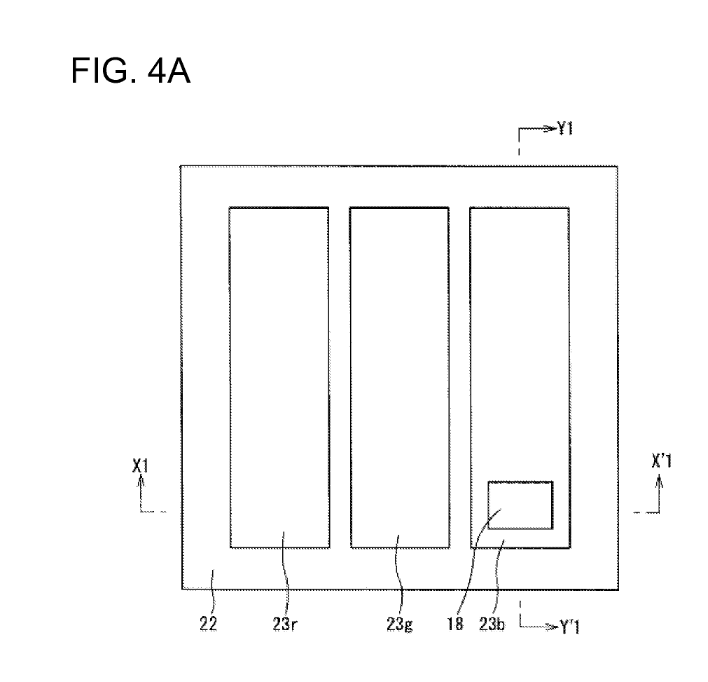

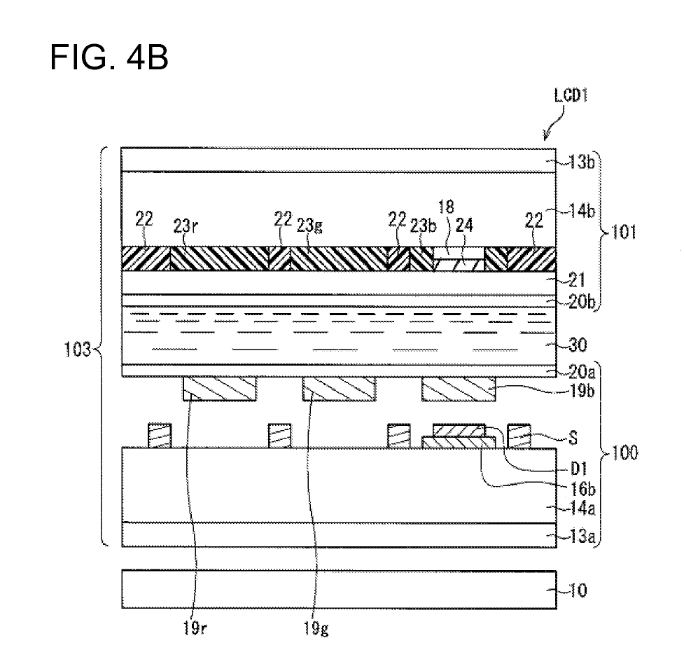

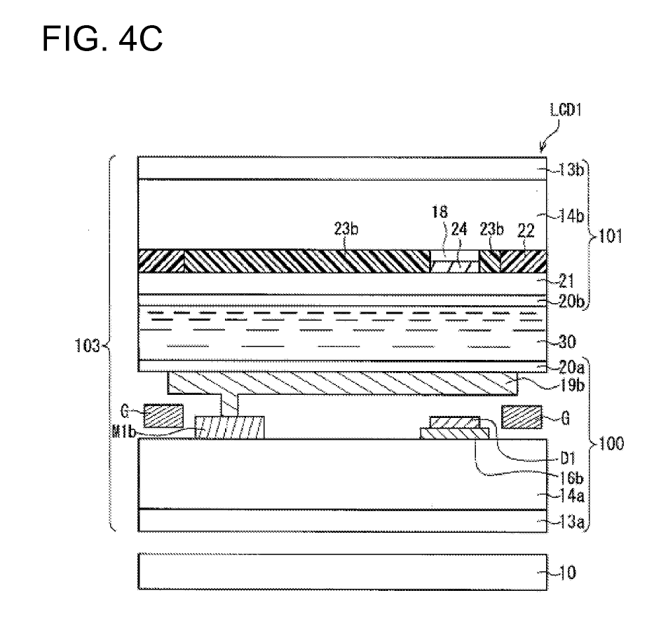

First, a configuration of a TFT substrate 100 included in a liquid crystal display device LCD1 (see FIGS. 4B and 4C), which is a display device according to Embodiment 1 of the present invention, will be explained with reference to FIGS. 1 and 2.

Configuration of TFT Substrate

FIG. 1 is a block diagram showing a schematic configuration of the TFT substrate 100 included in the liquid crystal display device LCD1. As shown in FIG. 1, the TFT substrate 100 includes, on a glass substrate, at least a pixel region 1, a display gate driver 2, a display source driver 3, a sensor column driver 4, a sensor row driver 5, a buffer amplifier 6, and an FPC connector 7. A signal processing circuit 8 that processes image signals received by photosensors FS (see FIG. 2) disposed in the pixel region 1, which will be described below, is connected to the TFT substrate 100 through the FPC connector 7 and an FPC 9.

In the pixel region 1, pixel circuits that include a plurality of pixels for displaying an image are formed. The pixel region 1 corresponds to a display region. In this embodiment, the respective pixels in the pixel circuits are provided with photosensors FS for capturing an image. The pixel circuits are connected to the display gate driver 2 through m number of gate lines G1 to Gm. The pixel circuits are connected to the display source driver 3 through 3n number of source lines Sr1 to Sm, Sg1 to Sgn, and Sb1 to Sbn. The pixel circuits are connected to the sensor row driver 5 through m number of reset signal lines RS1 to RSm and m number of read-out signal lines RW1 to RWm. The pixel circuits are connected to the sensor column driver 4 through n number of sensor output lines SS1 to SSn.

The above-mentioned constituting members on the TFT substrate 100 can also be formed monolithically on the glass substrate by a semiconductor process. Alternatively, the amplifier, the drivers and the like of these constituting members can be mounted on the glass substrate by COG (Chip On Glass) technique or the like, for example, or at least some of these constituting members shown on the TFT substrate 100 in FIG. 1 may be mounted on the FPC 9. A common electrode 21 (see FIGS. 4B and 4C) is formed on the entire surface of the TFT substrate 100, and thereafter, the TFT substrate 100 is bonded to an opposite substrate 101 (see FIGS. 4B and 4C) that will be later described. A liquid crystal material is sealed in a gap between the TFT substrate 100 and the opposite substrate 101.

On the rear surface of the TFT substrate 100, a backlight 10 is provided. The backlight 10 includes white LEDs (Light Emitting Diodes) 11 that emit while light (visible light) and infrared LEDs 12 that emit infrared light (IR light). In this embodiment, the infrared LEDs 12 are used as an example of a light emitter provided for emitting light that becomes signal light of the photosensors FS. That is, the infrared LEDs 12 are an example of the prescribed wavelength light source that emits light in a specific wavelength range that includes a range outside of the visible light range. The while LEDs 11 are light emitters that emit light for a display. The light emitters in the backlight 10 are not limited to these examples. As a light emitter for visible light, a combination of a red LED, a green LED, and a blue LED may be used, for example. CCFLs (Cold Cathode Fluorescent Lamps) may also be used instead of the LEDs.

Configuration of Display Circuit

FIG. 2 is an equivalent circuit diagram showing an arrangement of the pixel and the photosensor FS in the pixel region 1 of the TFT substrate 100. In the example of FIG. 2, one pixel is formed of three picture elements (sub-pixels) of three colors of R (red), G (green), and B (blue). In one pixel constituted of these three sub-pixels, one photosensor FS is provided. The pixel region 1 includes the pixels arranged in a matrix of m rows×n columns, and the photosensors FS arranged in the same manner, which is in a matrix of m rows×n columns. The number of sub-pixels is represented by m×3n as described above.

As shown in FIG. 2, the pixel region 1 has the gate lines G and the source lines Sr, Sg, and Sb that are arranged in a grid pattern as wiring lines for the pixels. The gate lines G are connected to the display gate driver 2. The source lines Sr, Sg, and Sb are connected to the display source driver 3. The gate lines G are provided for m rows in the pixel region 1. When it is necessary to explain the respective gate lines G individually below, each gate line is represented as Gi (i=1 to m). On the other hand, as described above, the source lines Sr, Sg, and Sb are provided such that one pixel has three source lines, thereby allowing the image data to be supplied to the three sub-pixels in one pixel, respectively. When it is necessary to explain the respective source lines Sr, Sg, and Sb individually, each source line is represented as Srj, Sgj, or Sbj (j=1 to n).

At each of the intersections of the gate lines G and the source lines Sr, Sg, and Sb, a thin film transistor (TFT) M1 is provided as a switching element for the pixel. In FIG. 2, the thin film transistors M1 provided in the respective sub-pixels of red, green, and blue are represented as M1r, M1g, and M1b. The gate electrodes of the thin film transistors M1 are connected to the gate lines G. The source electrodes of the thin film transistors M1 are connected to the source lines S. The drain electrodes of the thin film transistors M1 are connected to not-shown pixel electrodes. This way, as shown in FIG. 2, between the drain electrodes of the thin film transistors M1 and an opposite electrode (VCOM), liquid crystal capacitances C_{LC} are formed, respectively. Between the drain electrodes and TFTCOM, auxiliary capacitances C_{LS} are formed, respectively.

In FIG. 2, a red color filter is formed in a sub-pixel that is driven by the thin film transistor M1r, which is connected to the intersection of one gate line Gi and one source line Srj, so as to correspond to the sub-pixel. This sub-pixel, which is driven by the thin film transistor M1r, receives red image data from the display source driver 3 through the source line Srj, thereby serving as a red sub-pixel. A green color filter is formed in a sub-pixel that is driven by the thin film transistor M1g, which is connected to the intersection of one gate line Gi and one source line Sgj, so as to correspond to the sub-pixel. This sub-pixel, which is driven by the thin film transistor M1g, receives green image data from the display source driver 3 through the source line Sgj, thereby serving as a green sub-pixel. A blue color filter is formed in a sub-pixel that is driven by the thin film transistor M1b, which is connected to the intersection of one gate line Gi and one source line Sbj, so as to correspond to the sub-pixel. This sub-pixel, which is driven by the thin film transistor M1b, receives blue image data from the display source driver 3 through the source line Sbj, thereby serving as a blue sub-pixel.

In the example of FIG. 2, the photosensors FS are provided in the pixel region 1 such that one pixel (three sub-pixels) has one photosensor FS. However, the ratio of the photosensors to the pixels is not limited to this example, and may be appropriately selected. One photosensor may be provided for one sub-pixel, or one photosensor may be provided for a plurality of pixels, for example.

Configuration of Photosensor Circuit

As shown in FIG. 2, the photosensor FS includes a photodiode D1, which is an example of a photodetector element, a capacitor C1, and a transistor M2, which is an example of a switching element. The number of photodiodes included in the photosensor is not limited to one. The photosensor may include a plurality of photodiodes, for example. The anode of the photodiode D1 is connected to the reset signal line RS that supplies a reset signal. The cathode of the photodiode D1 is connected to the gate of the transistor M2. A node on the wiring line that connects the photodiode D1 to the gate of the transistor M2 is a storage node INT. One electrode of the capacitor C1 is also connected to the storage node INT. The other electrode of the capacitor C1 is connected to the read-out signal line RW that supplies a read-out signal. The drain of the transistor M2 is connected to a wiring line VDD. The source of the transistor M2 is connected to a wiring line OUT. The wiring line VDD is provided for supplying a fixed voltage V_{DD} to the photosensor FS. The wiring line OUT is an example of an output wiring line that outputs an output signal of the photosensor FS.

In the circuit configuration shown in FIG. 2, when the reset signal is supplied through the reset signal line RS, a potential V_{INT} of the storage node INT is initialized. After receiving the reset signal, the photodiode D1 becomes reverse-biased. When the read-out signal is supplied from the read-out signal line RW to the storage node INT through the capacitor C1, the potential V_{INT} of the storage node INT is boosted, which turns the transistor M2 on. As a result, an output signal corresponding to the potential V_{INT} of the storage node INT is output to the wiring line OUT. In this circuit, during a period between the end of the supply of the reset signal and the start of the supply of the read-out signal (integral interval), a current corresponding to a received light amount flows through the photodiode D1. This causes electrical charges corresponding to this current to flow out from the capacitor C1. Therefore, the potential V_{INT} of the storage node INT upon supply of the read-out signal is changed in accordance with the current that flowed through the photodiode D1. Because the output signal corresponding to the potential V_{INT} of the storage node INT is output to the wiring line OUT, the amount of light received by the photodiode D1 is represented by this output signal. The sensor circuit is not limited to such an example.

In the example of FIG. 2, the source line Sr doubles as the wiring line VDD that supplies the fixed voltage V_{DD} from the sensor column driver 4 to the photosensor FS. The source line Sg doubles as the wiring line OUT for the sensor output. The reset signal lines RS and the read-out signal lines RW are connected to the sensor row driver 5. These reset signal lines RS and the read-out signal lines RW are provided in the respective rows. When it is necessary to explain the respective wiring lines individually below, each line is represented as RSi or RWi (i=1 to m).

The sensor row driver 5 sequentially selects the reset signal lines RSi and the read-out signal lines RWi shown in FIG. 2 at a prescribed interval t_{row}. This way, the photosensors FS, from which the signal charges are to be read out, are sequentially selected row by row in the pixel region 1.

As shown in FIG. 2, an end of the wiring line OUT is connected to the drain of a transistor M3. The transistor M3 may be an insulated gate field effect transistor, for example. The drain of this transistor M3 is connected to an output wiring line SOUT, and therefore, a potential V_{SOUT} of the drain of the transistor M3 is output to the sensor column driver 4 as an output signal from the photosensor FS. The source of the transistor M3 is connected to a wiring line VSS. The gate of the transistor M3 is connected to a reference voltage source (not shown) through a reference voltage wiring line VB.

### OPERATION EXAMPLE

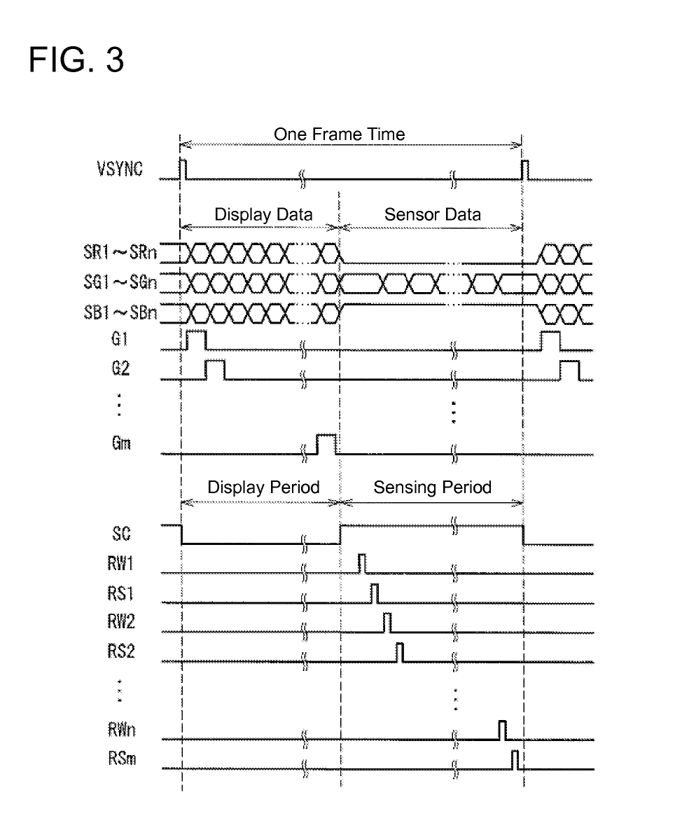

FIG. 3 is an example of a timing chart in driving the liquid crystal display device LCD1. In the example shown in FIG. 3, a vertical synchronization signal VSYNC is set to a high level in every frame time. One frame time is divided into a display period and a sensing period. A sensing signal SC is a signal that indicates whether the current period is the display period or the sensing period. The sensing signal SC is set to a low level during the display period, and is raised to a high level during the sensing period.

In the display period, the display source driver 3 supplies display data signals to the source lines Sr, Sg, and Sb. The display gate driver 2 sequentially raises a voltage of the gate lines G1 to Gm to a high level during the display period. When the voltage of the gate line Gi is at the high level, the source lines Sr1 to Sm, Sg1 to Sgn, and Sb1 to Sbn are respectively provided with voltages that correspond to gradation levels (pixel values) of the respective 3n sub-pixels that are connected to that gate line Gi.

During the sensing period, the fixed voltage V_{DD} is applied to the source lines Sr1 to Sm. The sensor row driver 5 sequentially selects the reset signal lines RSi and the read-out signal lines RWi row by row at the prescribed interval t_{row} during the sensing period. The reset signal line RSi and the read-out signal line RWi of the selected row are provided with the reset signal and the read-out signal, respectively. Voltages that correspond to amounts of light detected by the n number of photosensors FS, which are connected to the read-out signal line RWi of the selected row, are output to the source lines Sg1 to Sgn.

Configuration Example of Liquid Crystal Display Device

FIG. 4A is a top view of a region that corresponds to one pixel in the pixel region 1 of the liquid crystal display device LCD1 according to this embodiment. FIG. 4B is a cross-sectional view along the line X1-X′1 in FIG. 4A. FIG. 4C is a cross-sectional view along the line Y1-Y′1 in FIG. 4A. FIGS. 4A, 4B, and 4C illustrate a configuration example when one photosensor is provided for one sub-pixel. As shown in FIGS. 4B and 4C, the liquid crystal display device LCD1 of this embodiment includes a liquid crystal panel 103 and the backlight 10. In the liquid crystal panel 103, a first substrate (TFT substrate 100) having pixel circuits and a second substrate (opposite substrate 101) having color filters 23r, 23g, and 23b are disposed so as to face each other through a liquid crystal layer 30. There is no special limitation on an arrangement pattern of the color filters 23r, 23g, and 23b. In this embodiment, of the two surfaces of the liquid crystal panel 103, one on the side of the opposite substrate 101 is the front surface, and the other on the side of the TFT substrate 100 is the rear surface. That is, of the two surfaces of the liquid crystal panel 103, one on the side of the opposite substrate 101 (front surface) is an image display surface. The backlight 10 is provided on the rear surface side of the liquid crystal panel 103. That is, the backlight 10 is provided on the TFT substrate 100 on the side opposite to the liquid crystal layer 30. Polarizing plates 13a and 13b are disposed on the rear surface and the front surface of the liquid crystal panel 103, respectively.

In the opposite substrate 101, a layer that includes color filters 23r, 23g, and 23b and a black matrix 22 is formed on the surface of the glass substrate 14b on the side of the liquid crystal layer 30. An opposite electrode 21 and an alignment film 20b are formed so as to cover this layer.

In the TFT substrate 100, a light shielding layer 16 is formed on the glass substrate 14a, and the photodiode D1 formed on the light shielding layer 16 at a position that corresponds to the color filter 23b in the sub-pixel that is formed on the glass substrate 14b. The light shielding layer 16 is an example of a blocking portion that is provided for preventing light emitted from the backlight 10 from directly affecting the operation of the photodiode D1.

Further, on the glass substrate 14a, the thin film transistors M1, the gate lines G, and the source lines S that constitute the pixel circuits are formed. On these thin film transistors M1, gate lines G, and source lines S, pixel electrodes 19r, 19g, and 19b that are respectively connected to the thin film transistors M1 through contact holes are formed. On the pixel electrodes 19r, 19g, and 19b, an alignment film 20a is formed.

In the color filter 23b of the opposite substrate 101, a visible light blocking filter 18 that blocks visible light and a wavelength conversion layer 24 that converts light in a specific wavelength range into visible light are laminated at a position that faces the photodiode D1 through the liquid crystal layer 30. The specific wavelength range described here is an infrared range as an example, but the specific wavelength range is not limited to the infrared range, and may be any ranges as long as it includes a range outside of the visible light range.

The visible light blocking filter 18 is disposed on an optical path of light that enters through the display surface and that reaches the photodiode D provided in the photosensor. The wavelength conversion layer 24 is disposed between the visible light blocking filter 18 and the photodiode D1. That is, on the optical path of the light that enters the photodiode D1 provided in the photosensor FS, (1) the visible light blocking filter 18 that blocks visible light, (2) the wavelength conversion layer 24 (UCP), and (3) the photodiode D1 provided in the photosensor FS are arranged in this order from the side closer to the entrance of the light. In this configuration, infrared light, i.e., the signal component, that entered through the display surface is converted into visible light by the UCP (wavelength conversion layer 24), and the photosensor FS detects the amount of the visible light. Therefore, the photodiode D1 in the photosensor FS can be made of the same material as that of an active region (semiconductor layer) of the transistor M1 that constitutes the pixel circuit such as polysilicon or amorphous silicon. Also, because the visible light blocking filter 18 is disposed on the wavelength conversion layer 24, it becomes possible to prevent the visible light that was converted by the wavelength conversion layer 24 from affecting the image display.

The wavelength conversion layer 24 is disposed on the optical path of the light that enters the photosensor FS so as to convert the optical wavelength. As the wavelength conversion layer 24, UCP (UP-CONERSION PHOSPHORS) can be used, for example. This UCP is capable of converting wavelengths of the invisible range to wavelengths of the high-sensitivity range. By the UCP, light having a wavelength in a range of 800 to 900 nm can be converted into light having a wavelength in a range of 400 to 450 nm, for example. As a composition of the UCP, NaYF₄:Er, NaYF₄:Yb,Er, or the like, which includes rare earth elements such as Yb and Er, can be used, for example. The UCP is made by the solution precipitation method or the like, and formed in a film shape. A method of manufacturing the UCP will be later described.

On this wavelength conversion layer 24, the visible light blocking filter 18 is disposed. As the visible light blocking filter 18, an infrared light transmissive filter that blocks visible light can be used, for example. The infrared light transmissive filter can suppress noise light that enters the photodiode D1. As the infrared light transmissive filter, a resin filter that is similar to the color filters 23r, 23g, and 23b can be used. The infrared light transmissive filter (visible light blocking filter 18) and the color filters 23r, 23g, and 23b can be made of a negative type photosensitive resist that is obtained by dispersing pigments or carbons in a base resin such as an acrylic resin or a polyimide resin, for example. This visible light blocking filter 18 can be made of the same material as that of the color filters 23r, 23g, and 23b. It is preferable that the visible light blocking filter 18 have a laminated structure of the blue (B) color filter and the red (R) color filter, for example. It is more preferable that the visible light blocking filter 18 have a laminated structure of the red (R) color filter, the green (G) color filter, and the blue (B) color filter.

As described above, by forming the visible light blocking filter 18 by laminating a plurality of infrared light transmissive filters that respectively pass light of different wavelength ranges, the wavelength range of the light that passes through the filter can be restricted. By using the visible light blocking filter 18 so as to block noise light that has wavelengths in a range that is outside of the wavelength range of the light emitted from the infrared LEDs 12, for example, the S/N ratio of the photosensor FS can be improved.

The opposite substrate 101 may also have an air layer or a transparent resin layer on the polarizing plate 13b, and may further include a protective plate thereon. The protective plate is a transparent plate such as an acrylic plate, for example. This way, the protective plate can be disposed as the outermost layer that is touched by a user's finger. The polarizing plate 13b may include a polarizer that passes light that vibrates in a specific direction only and TAC films sandwiching the polarizer from both sides, for example. The protective plate may not be provided, or TAC films may not be provided.

Manufacturing Method

Next, a method for manufacturing the liquid crystal display device LCD1 according to this embodiment will be explained. In a process of manufacturing the TFT substrate 100, first, on a mother glass, which is an example of a base substrate, electrodes, TFTs, and photodiodes that form the pixel circuits are formed in respective regions that become a plurality of TFT substrates 100. In a process of manufacturing the opposite substrate 101, the visible light blocking filter 18 and the wavelength conversion layer 24 are formed by performing resist coating, exposure, development, and baking.

The TFT substrate 100 and the opposite substrate 101 that have been prepared in the manner describe above are bonded by a sealant, and liquid crystals are sealed therebetween. This way, the liquid crystal panel 103 is manufactured. The backlight 10 is attached to the rear surface of the liquid crystal panel 103.

Below, the process of manufacturing the TFT substrate 100 shown in FIGS. 4A and 4B will be explained. First, a metal film that later becomes the light shielding layers 16 is formed on the glass substrate 14a by sputtering. Thereafter, the metal film is patterned by the photolithography. As a result, the light shielding layers 16 are formed at prescribed positions on the glass substrate 14a. Next, CVD (Chemical Vapor Deposition) is performed to form an underlying film (not shown) of SiO₂. Thereafter, a semiconductor film, which later becomes semiconductor layers that form the photodiodes D1 and the thin film transistors M1, is formed by CVD, and the semiconductor film is patterned by the photolithography. As a result, the semiconductor layers that form the photodiodes D1 and the thin film transistors M1 are formed at prescribed positions on the glass substrate 14a. As described above, the photodiodes D1 and the thin film transistors M1 can be formed on the glass substrate 14a by using polysilicon, amorphous silicon, or the like. Next, a gate insulating film, a metal film, an interlayer insulating film, contact holes, a metal film that covers the contact holes, a protective film, the pixel electrodes 19r, 19g, and 19b, the alignment film 20a, and the like are formed.

In the process of manufacturing the opposite substrate 101, on a transparent mother glass, for example, the visible light blocking filters 18, the color filters 23r, 23g, and 23b, the black matrix 22, the wavelength conversion layers 24 (UCP), the opposite electrode 21, the alignment film 20b, and the like are formed. As the color filters, filter layers of three colors of red, green, and blue are formed in the respective pixels that are formed in display regions (pixel regions 1) of a plurality of liquid crystal panels 103, for example.

Below, a method of forming the wavelength conversion layer 24 (UCP) and a thick film coating process will be explained. As the method of forming the UCP, the solution precipitation method can be employed. As the solute, NaR, YR₃, or ErR₃ (R═CF₃COO) can be used, for example. As the solvent, a solution of a 50:50 mix of oleic acid (OA) and octadecene (ODE) can be used. The process of manufacturing the UCP includes the following step, for example.

First, a solution obtained by dissolving the solute in the solvent is heated in argon, thereby causing nanoparticles of NaYF₄ to form a solid.

After cooled to room temperature, the solution is mixed with hexane, and is washed repeatedly with a solvent such as THF or butyl ether. Thereafter, the solution is dried, and undergoes annealing or laser crystallization so as to increase the grain size.

The grain size of the UCP can be controlled by the concentration of the solution, the reaction time, and the subsequent annealing at higher temperature. By removing organic residue using THF, butyl ether, or other solvents as described above, the conversion efficiency can be further improved.

Next, an example of the thick film coding process of the UCP will be explained. The thick film coding process of the UCP includes the following steps (1) to (5), for example: (1) making nanoparticles of NaYF₄Er by the solution precipitation method; (2) mixing the nanoparticles of NaYF₄Er in diethylhexanoic acid, and heating the mixture; (3) cooling the mixture to room temperature, and adding methanol and water; (4) leaving the mixture under ultrasonic vibration for a prescribed period of time, followed by coating; and (5) heating the mixture to remove the solution.

The manufacturing method of the liquid crystal panel 103 and the manufacturing method of the UCP have been explained. However, the manufacturing method of the liquid crystal panel 103 and the manufacturing method of the UCP are not limited to the examples above.

### Embodiment 2

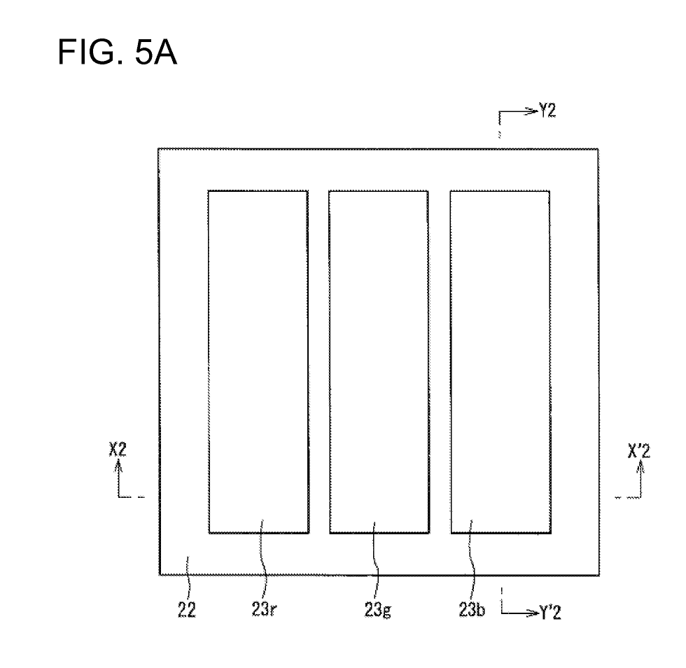

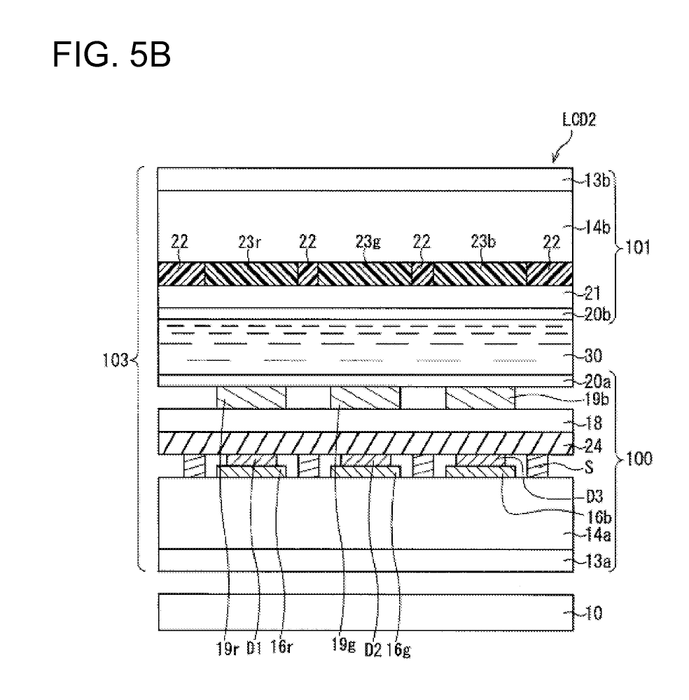

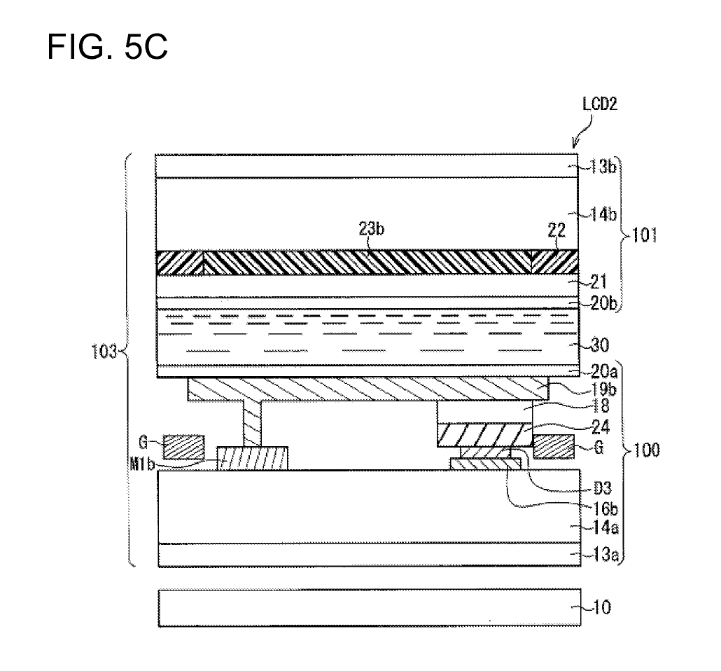

FIG. 5A is a top view of a region corresponding to one pixel in a pixel region 1 of a liquid crystal display device LCD2, which is a display device according to Embodiment 2. FIG. 5B is a cross-sectional view along the line X2-X′2 in FIG. 5A. FIG. 5C is a cross-sectional view along the line Y2-Y′2 in FIG. 5A. In the liquid crystal display device LCD2 shown in FIGS. 5A to 5C, the same reference characters are given to the same members as those of the liquid crystal display device LCD1 shown in FIGS. 4A to 4C. In the example shown in FIGS. 5A to 5C, the visible light blocking filter 18 and the wavelength conversion layer 24 are formed in the TFT substrate 100, instead of the opposite substrate 101.

That is, the wavelength conversion layer 24 and the visible light blocking filter 18 are disposed so as to cover the photodiodes D1, D2, and D3 of the photosensors FS that are formed on the TFT substrate 100. With these visible light blocking filter 18 and wavelength conversion layer 24 disposed so as to cover the photodiodes D1, D2, and D3 of the photosensors FS, noise light can be prevented from entering the photodiodes D1, D2, and D3. The visible light blocking filter 18 and the wavelength conversion layer 24 are formed between the photodiodes D1, D2, and D3 and the liquid crystal layer 30. This prevents noise light from entering the photodiodes D1, D2, and D3 more effectively as compared with the case in which the visible light blocking filter 18 and the wavelength conversion layer 24 are formed in the opposite substrate 101.

In the example shown in FIGS. 5A to 5C, the visible light blocking filter 18 is formed as a single film that covers the three photodiodes D1, D2, and D3, which are disposed so as to correspond to the red sub-pixel, the blue sub-pixel, and the green sub-pixel, respectively, for example. This makes it possible to prevent the noise light from entering the photodiodes D1, D2, and D3 even more efficiently.

It can also be configured such that the wavelength conversion layer 24 is disposed between the photodiodes D1, D2, and D3 of the photosensors FS and the liquid crystal layer 30 in the TFT substrate 100, and the visible light blocking filter 18 is disposed in the opposite substrate 101. The noise light can also be prevented from entering the photodiodes D1, D2, and D3 of the photosensors FS with this configuration.

Explanations of Effects and Other

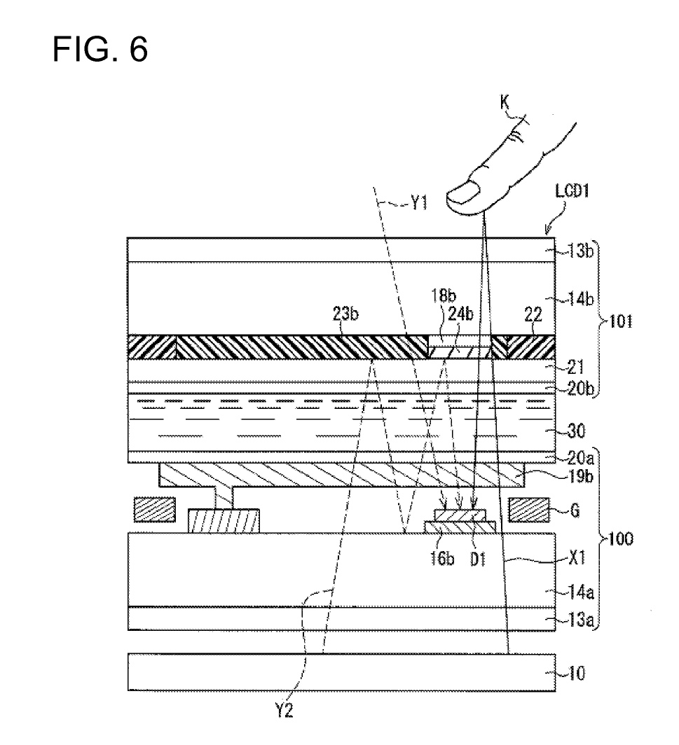

FIG. 6 is a cross-sectional view showing a configuration example of the liquid crystal display device LCD1 in which the visible light blocking filter 18 and the wavelength conversion layer 24 are disposed in the opposite substrate 101. The configuration shown in FIG. 6 is the same as that of FIG. 4C. In the configuration shown in FIG. 6, the opposite substrate 101 and the TFT substrate 100 are aligned to each other such that the visible light blocking filter 18 is located at a position that corresponds to the photodiode D1.

In the example shown in FIG. 6, as indicated by a solid arrow X1, infrared light emitted from the backlight 10 goes out through the surface of the liquid crystal panel 103, and the light reflected off a detection target K enters the photodiode D1 through the visible light blocking filter 18. This incident light becomes signal light for the photodiode D1 of the photosensor FS. On the other hand, as indicated by a broken arrow Y1 in FIG. 6, ambient light that enters through an opening of the pixel where the color filter 23b is disposed may be incident on the photodiode D1. This ambient light becomes a noise component for the photodiode D1. If the photodiode D1 and visible light blocking filter 18 are misaligned to each other due to an error in positioning in the step of bonding the TFT substrate 100 and the opposite substrate 101, the noise light is further increased. Also, as indicated by the broken arrows Y1 and Y2 in FIG. 6, because the TFT substrate 100 and the opposite substrate 101 have a gap therebetween such as the liquid crystal layer 30, ambient light that entered through the opening of the pixel or light that entered from the rear surface side (the side close to the backlight 10) of the liquid crystal panel 103 may be internally reflected and enter the photodiode D1, for example. Such light also becomes noise light for the photodiode D1.

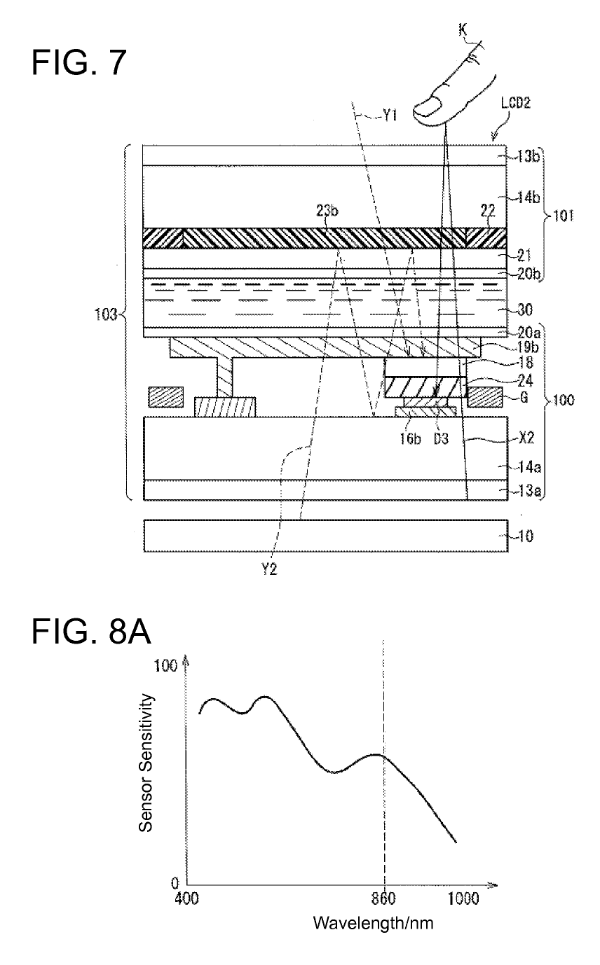

FIG. 7 is a diagram for explaining an example of a light beam in the liquid crystal display device LCD2 of Embodiment 2. As indicated by a solid arrow X2 as an example, infrared light emitted from the infrared LEDs 12 of the backlight 10 goes out through the surface of the liquid crystal panel 103. At this time, if a detection target K such as a finger is present on or near the surface of the liquid crystal panel 103, the infrared light is reflected by the detection target K, and is passing through the glass substrate 14b, the liquid crystal layer 30, the visible light blocking filter 18, the wavelength conversion layer 24, and the like to enter the photodiodes D1, D2, and D3. This incident light becomes signal light for the photodiodes D1, D2, and D3 of the photosensors FS. The photodiodes D1, D2, and D3 of the photosensors FS only receives, of the light from the backlight, visible light that was converted from the infrared light. Therefore, the photodiodes D1, D2, and D3 of the photosensors FS are capable of detecting visible light that represents a reflected image of the detection target K made by infrared light.

As shown in FIG. 7, by providing the visible light blocking filter 18 and the wavelength conversion layer 24 between the photodiodes D1, D2, and D3 and the liquid crystal layer 30 so as to cover the photodiodes D1, D2, and D3, ambient light (light indicated by the broken arrow Y1, for example) and internal reflection light (light indicated by the broken arrow Y2, for example), which become noise light, can be blocked by the visible light blocking filter 18. Even when the TFT substrate 100 and the opposite substrate 101 are misaligned, leaking light can be blocked by the visible light blocking filter 18, and therefore, noise light is not likely to be increased. That is, this configuration can solve the following problem: the visible light blocking filters 18 are offset from positions directly above the photodiodes D1, D2, and D3, thereby creating gaps, and ambient light and the like that entered through these gaps reaches the photodiodes D1, D2, and D3 as noise light, for example. As a result, the S/N ratio of the photodiodes D1, D2, and D3 can be improved. That is, it becomes possible to suppress the deterioration of the S/N ratio of the photodiodes D1, D2, and D3 caused by the error in positioning in bonding the TFT substrate 100 and the opposite substrate 101.

In the example of FIG. 7, it is not necessary to provide openings (opening for photosensors) in the color filters 23r, 23g, and 23b for disposing the visible light blocking filter 18 and the wavelength conversion layer 24. This allows for an improvement in the pixel aperture ratio (transmittance of the liquid crystal panel 103). Further, because these photosensor openings do not exist, light leakage from the photosensor openings can be eliminated, and as a result, the contrast of the liquid crystal panel 103 can be improved.

Also, undesired gaps between the visible light blocking filter 18 and the photodiodes D1, D2, and D3 can be eliminated. This leads to a reduction in the noise light that enters the photosensors FS such as internal reflection light, thereby improving the S/N ratio.

In the example shown in FIG. 7, the manner of detecting light that is emitted from the backlight 10 and that is reflected by the detection target K has been explained, but the method of detecting the detection target K is not limited to such. It is also possible to detect the detection target K by using infrared light included in ambient light in an environment (outdoor or a place illuminated by halogen lamps, for example) where ambient light includes infrared light (signal light for the photosensors), for example. In this case, when the detection target K is near the surface of the liquid crystal panel 103, ambient light that enters through the surface of the liquid crystal panel 103 is blocked by the detection target. That is, it becomes possible to detect a shadow of the detection target that is created by infrared light in the ambient light by the photosensors FS. The presence or absence of the detection target K can be determined based on amounts of light received by the photodiodes D1, D2, and D3, for example.

It is also possible to use the above-mentioned method of detecting the reflection light of the backlight 10 by the photosensors FS together with the method of detecting ambient light. The device can be configured such that, when ambient light includes infrared light, the backlight 10 is turned off, and the detection target K is detected through a shadow thereof created by ambient light, and when the ambient light does not include infrared light, the backlight 10 is turned on, and the detection target K is detected through a reflection image thereof created by infrared light emitted from the backlight 10, for example. The infrared light source may be provided in the opposite substrate 101.

Relationship between Visible Light Blocking Filter and Sensors

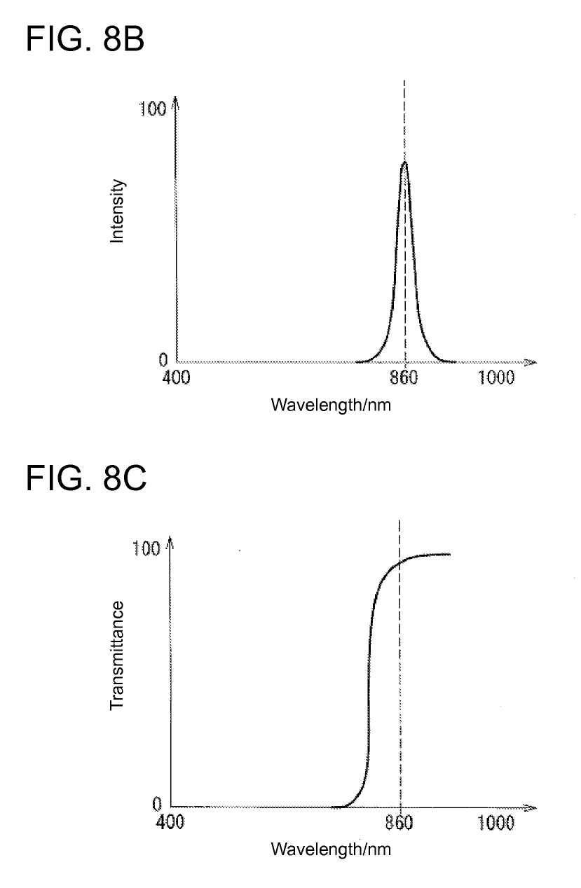

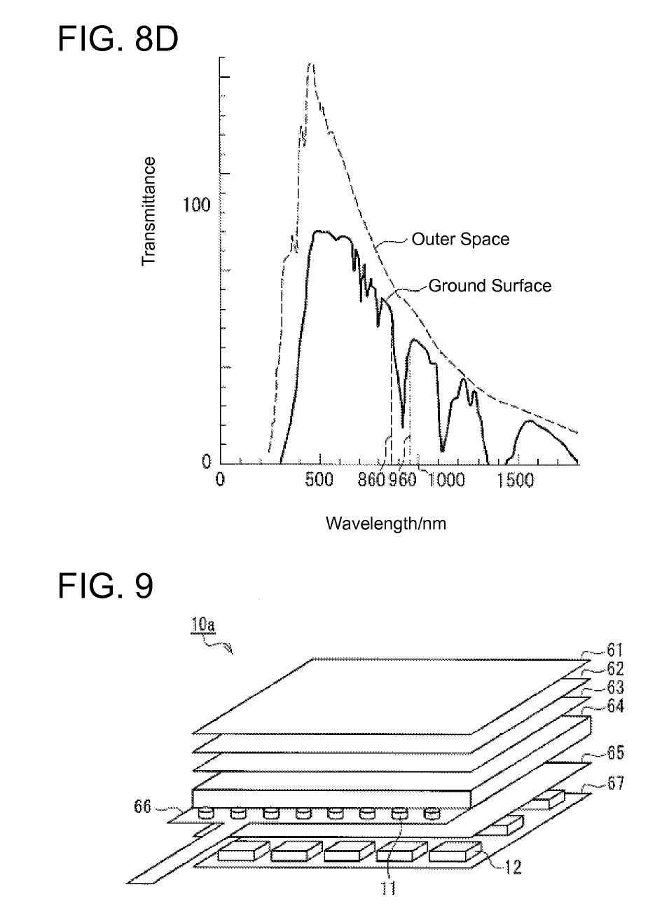

FIG. 8A is a graph showing an example of wavelength characteristics of the sensitivity of the photosensor FS employed in this embodiment. The photosensor FS is capable of sensing light having wavelengths in any range, and therefore, light having wavelengths in other ranges (such as ambient light and sunlight, for example) than the wavelength range of the light source that is provided for the sensors becomes noise. Thus, in this embodiment, any light having wavelengths in other ranges than the signal light range that is to be detected by the photosensors FS, i.e., light in the wavelength range that becomes noise, is blocked by the visible light blocking filter 18. Also, in this embodiment, the case where the range of the signal light that is to be detected by the photosensors FS (specific wavelength range) corresponds to the infrared light range has been described as an example, but the signal light range is not limited to the infrared light range.

When the method of detecting the reflection light of the backlight 10 by the photosensors FS is employed, the signal light range is determined by the wavelength of light emitted from a light source for photosensors. Therefore, as shown in FIG. 8A, when using the photosensor FS that can sense the light in the infrared light range with a higher sensitivity than light in the neighboring wavelength ranges, for example, it is preferable to use a light source that emits light of the infrared light range as the light source for the photosensors. This way, the signal light range can be set to the range that is detected by the photosensors FS with a higher sensitivity. FIG. 8B is a graph showing an example of the wavelength characteristics of light emitted from the infrared LEDs 12 that are employed in this embodiment.

It is preferable that the visible light blocking filter 18 pass light from the light source for the photosensors, and block any other light having different wavelengths. FIG. 8C is a graph showing an example of the filter characteristics of the infrared light transmissive filter that is employed in this embodiment. The filter having the filter characteristics shown in FIG. 8C can be suitably used when the light source for the photosensors emits infrared light, for example.

Infrared LEDs

Next, the backlight 10 including the infrared LEDs 12 will be explained in detail. As described above, on the path of the light entering the photodiode of the photosensor FS, the visible light blocking filter 18 and the wavelength conversion layer 24 are disposed. Therefore, a light source that emits infrared light, which has a wavelength in the range that passes through the visible light blocking filter 18, is used as the infrared LEDs 12. A light source that emits infrared light that has shorter wavelengths than the fundamental absorption edge wavelength (about 1100 nm) of silicon can be used as the infrared LEDs 12, for example. By using such infrared LEDs 12, when the pixel circuits 1 and the photodiodes of the photosensors FS are made of polycrystalline silicon, the infrared light emitted from the infrared LEDs 12 can be detected by the photosensors FS as visible light.

Alternatively, LEDs that emit infrared light having a peak wavelength thereof within the range of air absorption spectrum can be used as the infrared LEDs 12, and it is more preferable to use LEDs that emit infrared light having a peak wavelength thereof in a range of 860 nm to 960 nm. FIG. 8D is a diagram showing the typical spectrum of sunlight. The air absorption spectrum refers to the spectrum where the sunlight is attenuated by air. Specifically, it refers to the wavelength range from 780 nm to 820 nm with the attenuation peak at 800 nm, the wavelength range from 860 nm to 960 nm with the attenuation peak at 920 nm, and the like. In these wavelength ranges, sunlight is attenuated by being scattered by air and aerosol mainly made of nitrogen molecules and oxygen molecules or by being absorbed by water vapor and other molecules such as ozone, oxygen molecules, and carbon dioxide.

Sunlight is attenuated while passing through air in accordance with the above-mentioned air absorption spectrum, and becomes weaker on the surface of the ground than it is in outer space. In particular, the infrared light in the wavelength range of 860 nm to 960 nm is absorbed by water vapor in air, and is thereby significantly attenuated. When infrared LEDs 12 that emit infrared light in the wavelength range where the sunlight is weak as described above are used, by providing the band pass filter that passes infrared light in that wavelength range on the path of light that enters the photodiode of the photosensor FS, it becomes possible to reduce the effects of sunlight on a scanned image and to detect a touch position with a higher degree of accuracy.

The infrared light in this embodiment can also be used for other embodiments in the present specification.

FIGS. 9 to 13 respectively show examples of first to fifth configurations of the backlight 10. In each of backlights 10a to 10e shown in FIGS. 9 to 13, two lens sheets 61 and 62 and a diffusion sheet 63 are provided on one surface of a light guide plate 64 or 74, and on the other surface thereof, a reflective sheet 65 or 72 is provided.

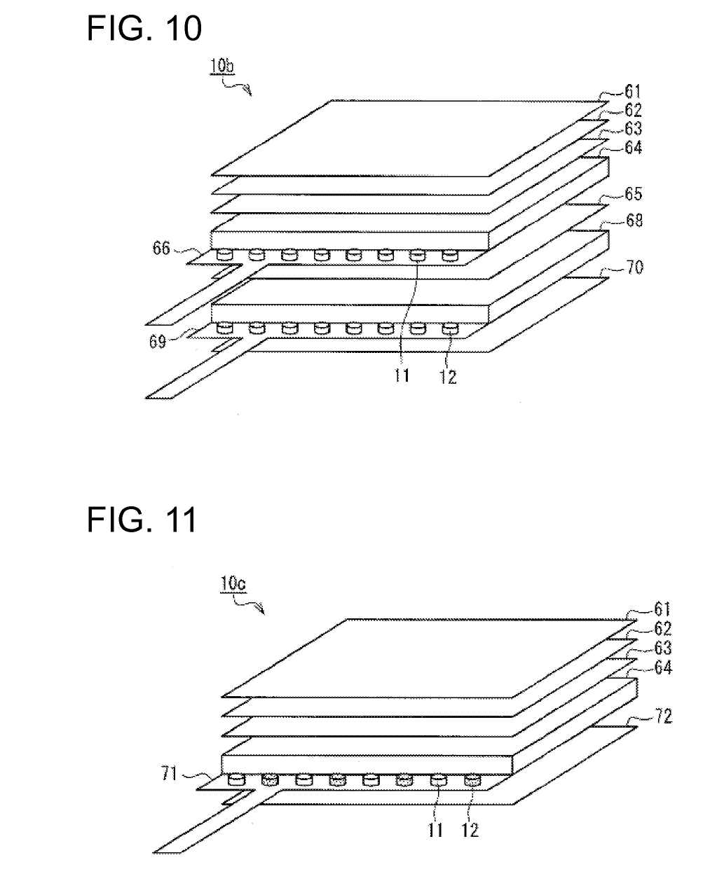

In the backlights 10a and 10b shown in FIGS. 9 and 10, a flexible printed board 66 having white LEDs 11 arranged thereon one-dimensionally is disposed on the side surface of the light guide plate 64, and an infrared light source is disposed on the light guide plate 64 on the side of the reflective sheet 65. In the backlight 10a, a circuit board 67 having infrared LEDs 12 arranged thereon two-dimensionally is provided as the infrared light source. In the backlight 10b, the infrared light source includes a light guide plate 68, a flexible printed board 69 (disposed on the side surface of the light guide plate 68) having the infrared LEDs 12 arranged thereon one-dimensionally, and a reflective sheet 70. As the reflective sheet 65, a sheet that passes infrared light and reflects visible light (a reflective sheet made of a polyester resin, for example) can be used. As a reflective sheet 70, a sheet that reflects infrared light can be used. As described above, by adding the infrared light source to a backlight that emits visible light, the backlight 10 that emits both infrared light and visible light can be achieved, using an existing backlight that emits visible light, for example.

In the backlight 10c shown in FIG. 11, a flexible printed board 71 having the white LEDs 11 and the infrared LEDs 12 arranged alternately on a single line is disposed on the side surface of the light guide plate 64. As a reflective sheet 72, a sheet that reflects both of visible light and infrared light can be used. As described above, by arranging the white LEDs 11 and the infrared LEDs 12 alternately along the side surface of the light guide plate 64, it becomes possible to achieve the backlight 10 that emits both visible light and infrared light while maintaining the structure similar to that of the backlight having the white LEDs 11 alone.

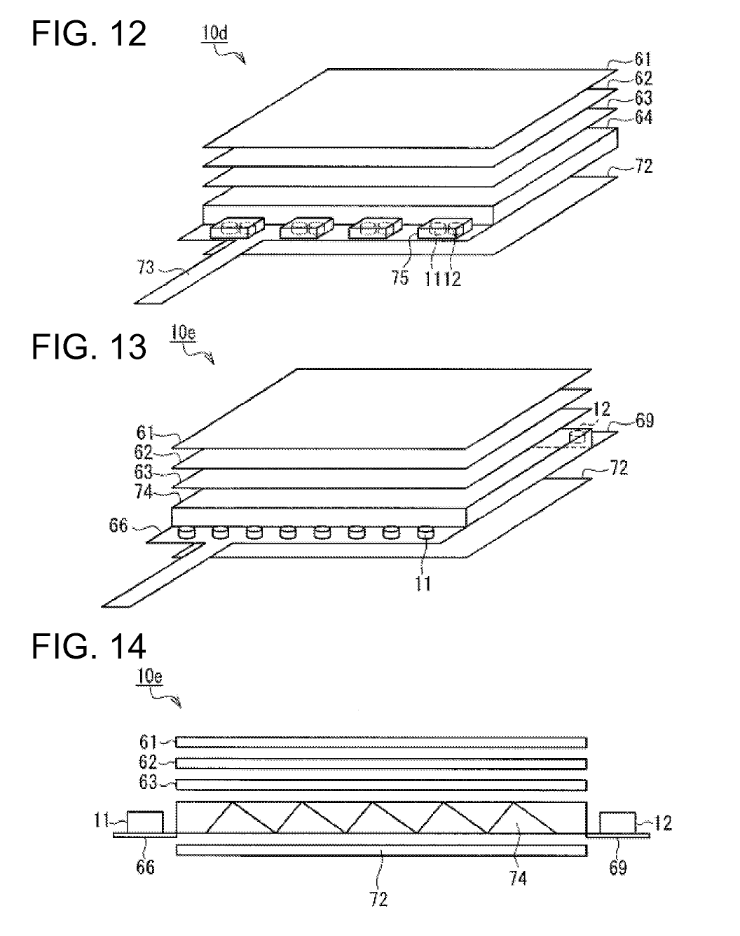

In the backlight 10d shown in FIG. 12, a flexible printed board 73 having resin packages 75 arranged thereon along a single line is disposed on the side surface of the light guide plate 64. The respective resin packages 75 include the white LEDs 11 and the infrared LEDs 12. By packaging the white LED 11 and the infrared LED 12 in the same resin package 75 in this way, a large number of LED light emitters can be efficiently arranged in small space. One resin package 75 may include one white LED 11 and one infrared LED 12, or may include the respective LEDs plurally.

In the backlight 10e shown in FIG. 13, a flexible printed board 66 having the white LEDs 11 arranged thereon one-dimensionally is provided on one side surface of a light guide plate 74, and a flexible printed board 69 having the infrared LEDs 12 arranged thereon one-dimensionally is provided on the side surface of the light guide plate 74, which is opposite to the side surface where the white LEDs 11 are arranged. FIG. 14 is a cross-sectional view of the backlight 10e. The light guide plate 74 is processed such that white light that enters through one side surface and infrared light that enters through the other side surface can travel therein, respectively. As described above, by respectively arranging the white LEDs 11 and the infrared LEDs 12 along the two side surfaces that face each other in the light guide plate 74, the same light guide plate and other backlight members can be commonly used for the two types of LEDs.

### Embodiment 3

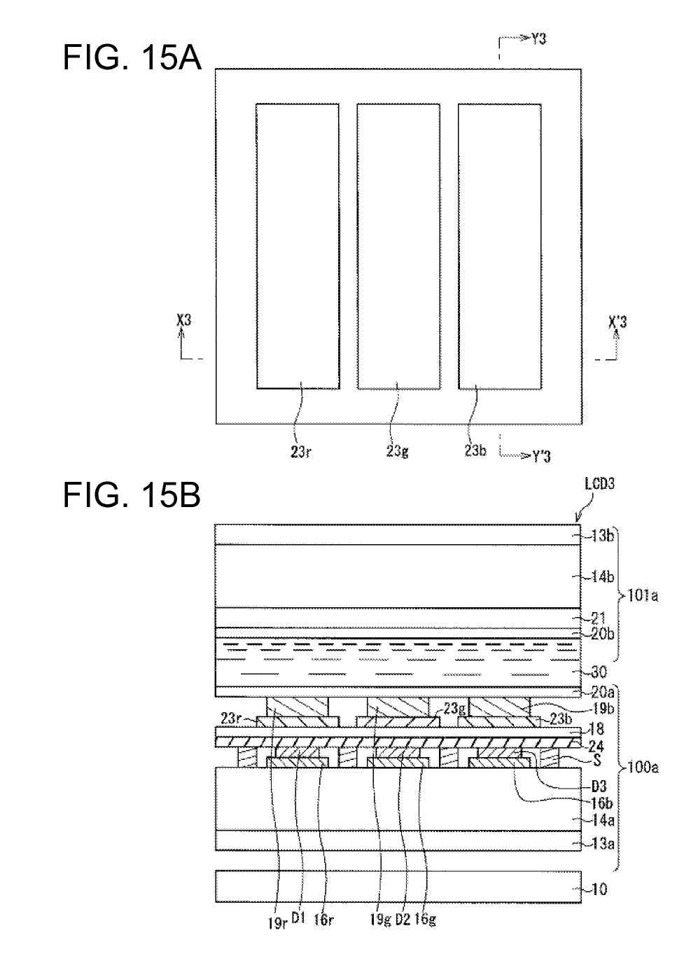

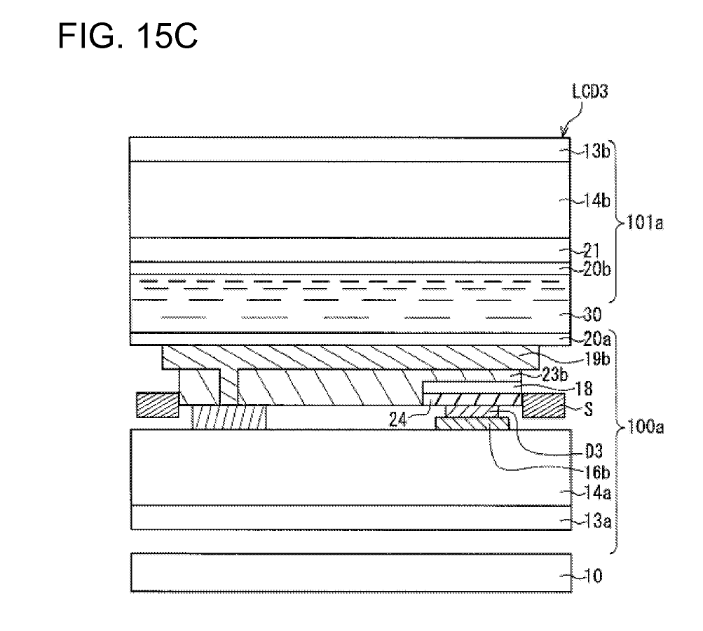

FIG. 15A is a top view of a region corresponding to one pixel in a pixel region 1 of a liquid crystal display device, which is a display device according to Embodiment 3. FIG. 15B is a cross-sectional view along the line X3-X′3 in FIG. 15A. FIG. 15C is a cross-sectional view along the line Y3-Y′3 in FIG. 15A. In contrast to Embodiment 1 where the color filters 23r, 23g, and 23b were formed in the opposite substrate 101, in this embodiment, the color filters 23r, 23g, and 23b are formed in the TFT substrate 100. As shown in FIGS. 15A to 15C, in a TFT substrate 100, the light shielding layers 16 are disposed on the glass substrate 14a, and on the light shielding layers 16, the photodiodes D1, D2, and D3 are formed. Further, on the glass substrate 14a, the thin film transistors M1, the gate lines G, and the source lines S, which constitute the pixel circuits, are formed. The wavelength conversion layer 24 and the visible light blocking filter 18 are disposed so as to cover the photodiodes D1, D2, and D3. On the visible light blocking filter 18, the red color filter 23r, the green color filter 23g, and the blue color filter 23b are disposed. The respective color filters 23r, 23g, and 23b are formed at positions that correspond to the respective sub-pixels. On the color filters 23r, 23g, and 23b, the pixel electrodes 19r, 19g, and 19b are disposed, respectively.

According to this embodiment, the color filters 23r, 23g, and 23b are formed in the TFT substrate 100a, and therefore, the black matrix can be eliminated, or the black matrix can be reduced, thereby improving the aperture ratio.

Further, in this embodiment, in a manner similar to Embodiment 2 above, the visible light blocking filter 18 and the wavelength conversion layer 24 are formed directly above the photodiodes D1, D2, and D3 of the photosensors FS. This can prevent ambient light from entering through the openings in the pixels, and therefore, the internal reflection of such light, which causes noise components for the photosensors FS, can be prevented. Also, it becomes possible to eliminate an undesired gap between the visible light blocking filter 18 and the photodiodes D1, D2, and D3 of the photosensors FS. This allows for a reduction in noise light such as internal reflection light that enters the photosensors FS, and as a result, the S/N ratio of the photosensors FS can be improved.

Further, when the color filters 23r, 23g, and 23b, the visible light blocking filter 18, and the wavelength conversion layer 24 are formed in the opposite substrate 101, part of the openings in the pixels are occupied by the visible light blocking filter 18, but in this embodiment, it is not necessary to form the openings in the color filters 23r, 23g, and 23b for disposing the visible light blocking filter 18 and the wavelength conversion layer 24, which improves the pixel aperture ratio (transmittance of the liquid crystal panel 103). Because the openings for the photosensors can also be eliminated, light leakage from such openings can be reduced, and as a result, the contrast of the liquid crystal panel 103 can be improved.

The positioning error of the color filters 23r, 23g, and 23b, which occurs in the step of bonding the opposite substrate 101a and the TFT substrate 100a, can also be eliminated, and therefore, it becomes possible to solve the problem of the visible light blocking filter 18 and the wavelength conversion layer 24 being offset from the positions that are directly above the photodiodes D1, D2, and D3 of the photosensors FS, causing noise light such as ambient light to enter the photodiodes D1, D2, and D3. As a result, the S/N ratio of the photosensors FS is improved.

The visible light blocking filter 18 and the color filters 23r, 23g, and 23b can be formed by using a negative type photosensitive resist that is obtained by dispersing pigments or carbons in a base resin. In the manufacturing process, both of the visible light blocking filter 18 and the color filters 23r, 23g, and 23b are formed in the process of manufacturing the TFT substrate 100, and therefore, the manufacturing efficiency is increased.

In Embodiments 1 to 3 above, the photodetector elements are not limited to the photodiodes, and phototransistors or the like can also be used as the photodetector elements, for example.

### INDUSTRIAL APPLICABILITY

The present invention is industrially applicable as a display device in which sensor circuits are provided in a pixel region of a TFT substrate thereof.

1. A display device that has a display region that displays an image, comprising:
a photosensor in the display region;
a visible light blocking filter that blocks visible light, the visible light blocking filter being disposed on an optical path of light that enters through a display surface of the image and that reaches the photosensor; and
a wavelength conversion layer that converts light in a specific wavelength range, which includes a range outside of a visible light range, into visible light, the wavelength conversion layer being provided between the visible light blocking filter and the photosensor.

2. The display device according to claim 1 further comprising a color filter that is disposed in the display region and that is used for displaying the image,
wherein the visible light blocking filter is made of a same material as that of the color filter.

3. The display device according to claim 2, wherein the visible light blocking filter is formed by laminating color filters of two colors among green, blue, and red.

4. The display device according to claim 2, wherein the visible light blocking filter is formed by laminating three color filters of green, blue, and red.

5. The display device according to claim 1, further comprising:
a first substrate having a pixel circuit that displays the image;
a liquid crystal layer; and
a second substrate that faces the first substrate through the liquid crystal layer,
wherein the photosensor is formed in the first substrate, and
wherein at least one of the visible light blocking filter and the wavelength conversion layer is disposed between the photosensor and the liquid crystal layer.

6. The display device according to claim 2, further comprising:
a first substrate having a pixel circuit that displays the image;
a liquid crystal layer; and
a second substrate that faces the first substrate through the liquid crystal layer,
wherein the photosensor is formed in the first substrate, and
wherein the color filter is disposed between the photosensor and the liquid crystal layer.

7. The display device according to claim 1, further comprising:
a first substrate having a pixel circuit that displays the image;
a liquid crystal layer; and
a second substrate that faces the first substrate through the liquid crystal layer,
wherein the photosensor and the pixel circuit are formed in the first substrate by using amorphous silicon or polysilicon.

8. The display device according to claim 1, further comprising a prescribed wavelength light source that emits light in the specific wavelength range,
wherein the photosensor detects, of light that emitted from the prescribed wavelength light source, light that enters through the visible light blocking filter and the wavelength conversion layer.

9. A method of manufacturing a display device, comprising:
forming a pixel circuit and a photosensor on a substrate;
forming a visible light blocking filter that blocks visible light at a position that corresponds to the photosensor; and
forming a wavelength conversion layer between the photosensor and the visible light blocking filter, the wavelength conversion layer converting light in a specific wavelength range, which includes a range outside of a visible light range, into visible light.
